(19) United States
(12) Patent Application Publication
(10) Pub. No.: US 2012/0228759 A1
(43) Pub. Date: Sep. 13, 2012

(54) SEMICONDUCTOR PACKAGE HAVING INTERCONNECTION OF DUAL PARALLEL WIRES

(76) Inventor: Wen-Jeng FAN, Hsinchu (TW)

(21) Appl. No.: 13/041,844

(22) Filed: Mar. 7, 2011

(51) Int. Cl. H01L 23/49

(52) U.S. Cl. 257/737; 257/E23.024

(57) ABSTRACT

A semiconductor package having dual parallel wires is disclosed. A chip is attached on a substrate where the chip and the substrate are electrically connected by a bonding wire. The bonding wire consists of a first metal wire, a second metal wire, and an insulating body where the insulating body encapsulates the first and the second metal wires to make both metal wires parallel to each other. The insulating body forms a constant gap between the first and the second metal wires so that both metal wires do not contact to each other. Therefore, the electrical performance of the package can greatly be enhanced with the same productivity.

### FIELD OF THE INVENTION

The present invention relates to semiconductor devices, more specifically to semiconductor packages having interconnection of dual parallel metal wires.

### BACKGROUND OF THE INVENTION

Inside conventional semiconductor packages, the electrical connections between the bonding pads on the active surface of a chip and the bonding fingers of a substrate are achieved by bonding wires through wire bonding processes. In order to increase current carrying capability between a chip and a substrate or/and to enhance the electrical performance of a chip, two or more bonding wires are bonded on the same bonding pad, then bonded to the same bonding finger of a substrate, especially for the power and ground pins. However, two separated wire bonding processes to bond two bonding wires are required which will greatly reduce the productivity. Moreover, these two bonding wires do not have the same wire lengths which are vulnerable for electrical short caused by mold flow that will impact the electrical performance.

As shown in FIG. 1, a conventional semiconductor package 100 primarily comprises a substrate 110 and a chip 120. A die-attaching layer 160 is disposed between the active surface 122 of the chip 120 and the top surface 112 of the substrate 110 to fix the chip 120 on the substrate 110. As shown in FIG. 2 and FIG. 3, one end of a first bonding wire 130A and one end of a second bonding wire 130B are bonded to a same bonding pad 121 of the chip 120 and the other ends to the corresponding bonding finger 111 of the substrate 110 to increase current carrying capability between the chip 120 and the substrate 110. Since the areas of the bonding pads of a chip are quite limited where two bonding wires are required to be bonded on the same one of the bonding pads, the ball bonds of two bonding wires have to be vertically bonded together as shown in FIG. 3. Therefore, the ball bond of the first bonding wire 130A is firstly bonded on the bonding pad 121 then bonded on the corresponding bonding finger 111 of the substrate 110. After that, the ball bond of the second bonding wire 130B is vertically and directly bonded on top of the ball bond of the first bonding wire 130A and then bonded on the same bonding finger 111 of the substrate 110 leading to changing the loop profile of the first bonding wire 130A. As shown in FIG. 4, after bonding two bonding wires, the second bonding wire 130B is on top of but not parallel to the first bonding wire 130A. An encapsulant 140 is formed on the top surface 112 of the substrate 110 and in the central slot 114 to encapsulate the chip 120, the die-attaching layer 160, the first bonding wire 130A and the second bonding wire 130B. A plurality of external terminals such as solder balls are disposed on the bottom surface 113 of the substrate 110 as the external electrical connections of the semiconductor package 100. Therefore, in order to achieve the electrical connections between the chip 120 and the substrate 110 through multiple bonding wires, two wire-bonding processes are required to dispose multiple bonding wires 130A and 130B on the same bonding pad 121 of the chip 120 where the wire-bonding processing time is double leading to lower productivity. Furthermore, since the first bonding wire 130A and the second bonding wire 130B are not parallel bonded, the middle section of both bonding wires will easily sweep and contact to each other leading to electrical short due to the impact of mold flow during the formation of the encapsulant 140. Moreover, the wire lengths of both bonding wires 130A and 130B are not the same, therefore, the enhanced electrical performance is limited.

### SUMMARY OF THE INVENTION

The main purpose of the present invention is to provide a semiconductor package having dual parallel wires where two metal wires parallel to each other are encapsulated in a single bonding wire are bonded on the same bonding pad, therefore, the electrical performance of the package can greatly be enhanced.

The second purpose of the present invention is to provide a semiconductor package having dual parallel wires to reduce the processing steps as well as processing time of wire-bonding to keep the same productivity as the electrical connections using a single bonding wire.

According to the present invention, a semiconductor package having dual parallel wires is revealed comprising a substrate, a chip, at least a bonding wire and an encapsulant where the substrate has at least a bonding finger. The chip is disposed on top of the substrate where the chip has at least a bonding pad. The bonding wire electrically connects the bonding pad and the bonding finger where the bonding wire consists of a first metal wire, a second metal wire, and an insulating body. The insulating body encapsulates the first metal wire and the second metal wire in a manner to make the two metal wires parallel to each other and to keep a constant gap between two metal wires so that two metal wires do not contact to each other leading to electrically short. The encapsulant encapsulates the bonding wire and the chip.

The semiconductor package having dual parallel wires according to the present invention has the following advantages and effects:
1. Through a specific combination including a bonding wire consisting of the first metal wire, the second metal wire, and the insulating body and its application in semiconductor packaging to electrically connect the substrate and the chip as a technical mean, the insulating body encapsulates the first metal wire and the second metal wire to provide a constant gap between two metal wires and to make both metal wires parallel to each other, therefore, the electrical performance of the semiconductor package can greatly be enhanced.
2. Through a specific combination including a bonding wire consisting of the first metal wire, the second metal wire, and the insulating body and its application in semiconductor packaging to electrically connect the substrate and the chip as a technical mean, the first metal wire and the second metal wire of the bonding wire can be bonded to the same contacts of the substrate and the chip during one single wire-bonding process, therefore, the processing steps as well as the processing time of wire bonding can greatly be reduced with the same productivity as the electrical connections using single bonding wires.

### DESCRIPTION OF THE DRAWINGS

FIG. 1 is a cross-sectional view of a conventional semiconductor package.

FIG. 2 is a partially perspective view of the conventional semiconductor package of FIG. 1 to show electrical connections using multiple bonding wires.

FIG. 3 is a partially cross-sectional view of the conventional semiconductor package of FIG. 1.

FIG. 4 is a circle cross-sectional view of four bonding wires in the conventional semiconductor package of FIG. 1.

FIG. 5 is a cross-sectional view of a semiconductor package having dual parallel wires according to the preferred embodiment of the present invention.

FIG. 6 is a partially linear cross-sectional view of a bonding wire in the semiconductor package of FIG. 5.

FIG. 7 is a circle cross-sectional view of two bonding wires in the semiconductor package of FIG. 5.

FIG. 8 is a partially cross-sectional view of the semiconductor package of FIG. 5.

FIG. 9 is a partially cross-sectional view of another semiconductor package according to the variational embodiment of the present invention.

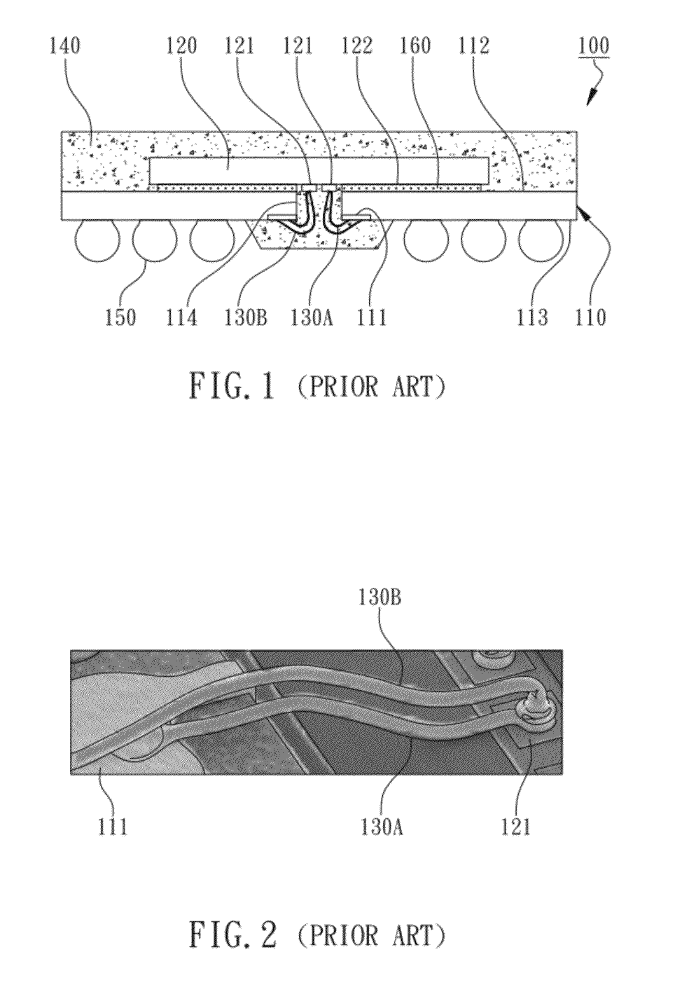

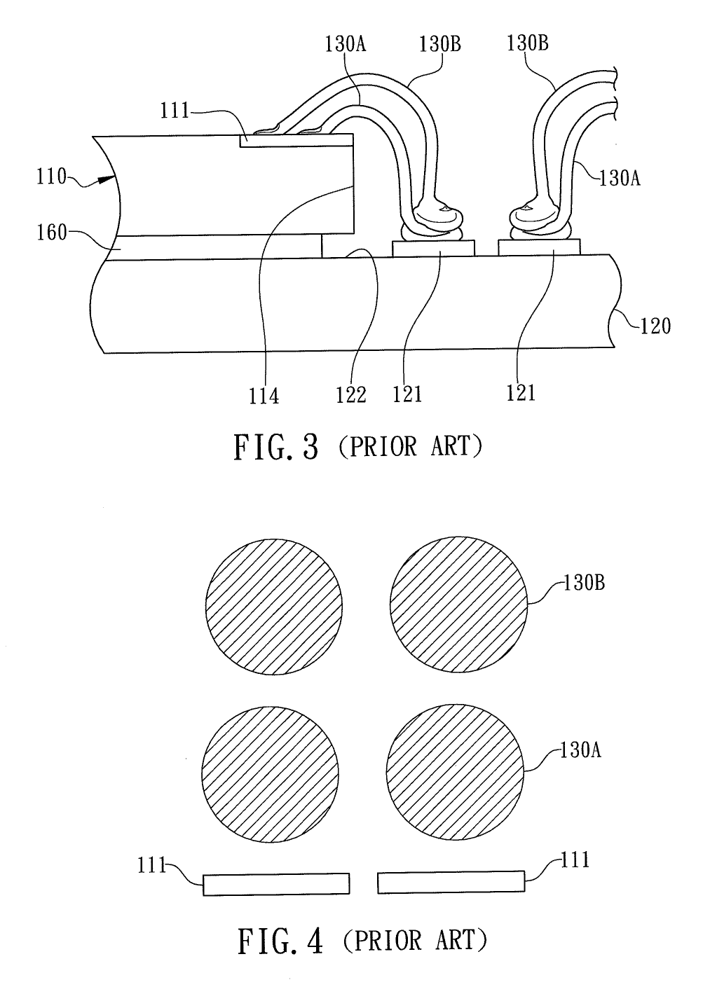

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

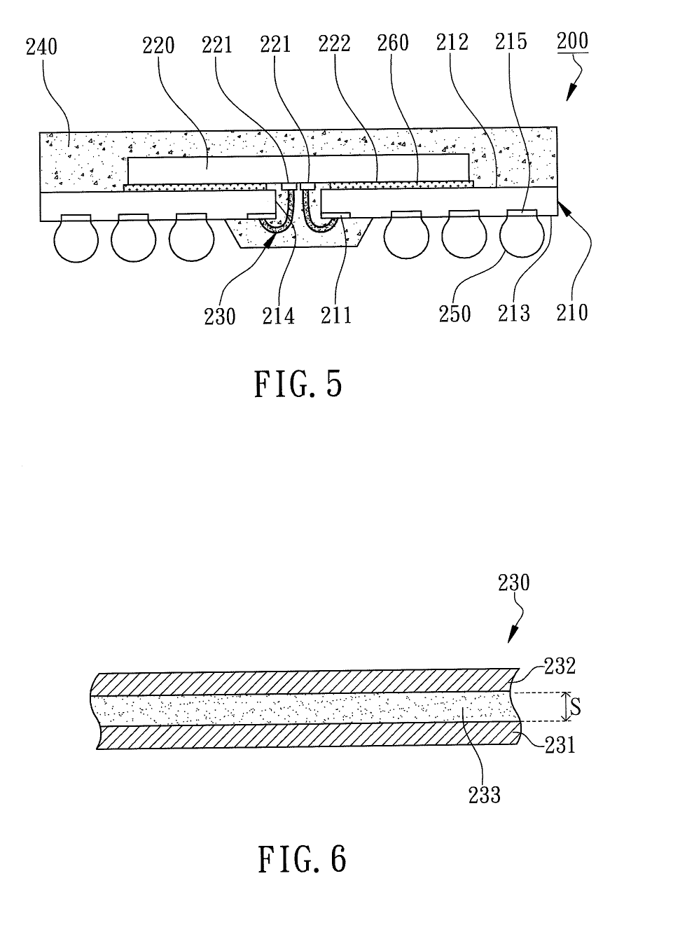

According to the preferred embodiment of the present invention, a semiconductor package having dual parallel wires is illustrated in FIG. 5 for cross-sectional view. The semiconductor package having dual parallel wires 200 comprises a substrate 210, a chip 220, at least a bonding wire 230, and an encapsulant 240. There are a plurality of bonding wires in actual package products.

As shown in FIG. 5, the substrate 210 has at least a bonding finger 211. The chip 220 is disposed on the substrate 210, and has at least one bonding pad 221. To be described in detail, the substrate 210 can be a printed circuit board (PCB) for carrying a chip and providing electrical connections. In the present embodiment, the semiconductor package 200 is a window-type BGA where the substrate 210 further has a top surface 212, a bottom surface 213, and a central slot 214 penetrating from the top surface 212 to the bottom surface 213. When the encapsulant 240 is formed on the top surface 212 of the substrate 210, the encapsulant 240 partially encapsulates the bottom surface 213 through the central slot 214 to completely encapsulate the bonding wire 230. An active surface 222 of the chip 220 is attached to the top surface 212 leading the bonding pad 221 of the chip 220 aligned to the central slot 214 so that the bonding wire 230 passing through the central slot 214 can be bonded onto the bonding pad 221. The wire length of the bonding wire 230 is reduced to provide faster signal transmitting speeds. In a preferred embodiment, the substrate 210 has a plurality of external connection pads 215. The bonding finger 211 and the external connection pads 215 are disposed on the bottom surface 213 of the substrate 210 where the bonding finger 211 is for internal electrical connection and the external connection pads 215 are for external electrical connections. Furthermore, the semiconductor package 200 further comprises a plurality of external terminals 250 disposed on the external connection pads 215. The external terminals 250 can be solder balls served as external electrical connections to printed circuit boards.

In actual package products, there are a plurality of bonding pads 221 with the same number as or more than the number of the bonding wire 230. To be described in detail, the chip 220 is a semiconductor device with IC such as memory, logic, or ASIC which is formed by dicing a wafer to become individual chips. In the present embodiment, the semiconductor package 200 further comprises a die-attaching layer 260 adhering the active surface 222 of the chip 220 to the top surface 212 of the substrate 210.

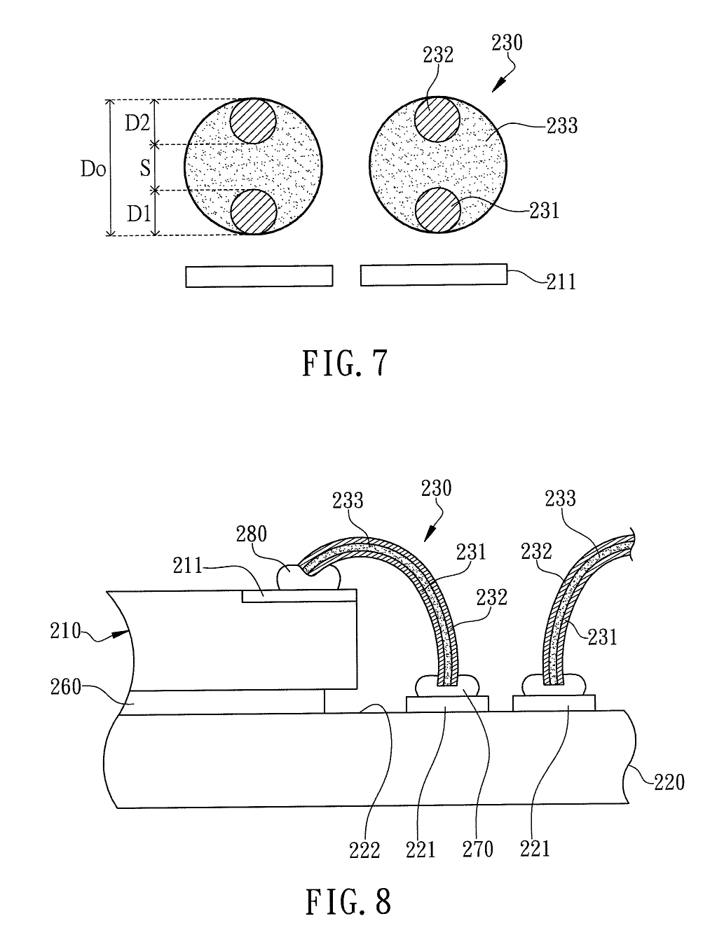

As shown in FIG. 5, the bonding wire 230 electrically connects the bonding pad 221 to the bonding finger 211. The bonding wire 230 is composite. As shown in FIG. 6 and FIG. 7, the bonding wire 230 comprises a first metal wire 231, a second metal wire 232, and an insulating body 233. In a preferred embodiment, the insulating body 233 is made of non-conductive materials to encapsulate the first metal wire 231 and the second metal wire 232 by coating and spinning processes. Therefore, the insulating body 233 encapsulates the first metal wire 231 and the second metal wire 232 in a manner to make the both metal wires 231 and 232 extending in parallel to each other and to provide a constant gap S between the first metal wire 231 and the second metal wire 232 so that the extending section of the first metal wire 231 and the second metal wire 232 do not contact to each other leading to electrical short. That is to say, the first metal wire 231 and the second metal wire 232 are always parallel to each other without contacting to each other even with different bending curves due to wire bonding requirements except two bonded ends of metal wires 231 and 232 connecting to the chip 220 and to the substrate 210.

FIG. 7 shows the circle cross-section of two bonding wires 230. Preferably, the length of the gap S is equal to the diameter D₀ of the insulating body 233 subtracting the diameter D₁ of the first metal wire 231 and the diameter D₂ of the second metal wire 232, the equation is S=D₀−D₁−D₂ so that the first metal wire 231 and the second metal wire 232 can individually and adjacent to a wire surface of the insulating body 233 which means that the first metal wire 231 and the second metal wire 232 are encapsulated by the insulating body 233 and neighbor closely on the wire surface of the insulating body 233. In a variation of embodiment, the first metal wire 231 and the second metal wire 232 can be partially exposed from the wire surface of the insulating body 233. In other words, the first metal wire 231 and the second metal wire 232 are not completely encapsulated by the insulating body 233 where two strips of metal gloss are shown on the wire surface so that the locations of both metal wires 231 and 232 can easily be recognized. Furthermore, in a preferred embodiment, the exposed portions of the first metal wire 231 and the second metal wire 232 do not face to the adjacent bonding wires 230 to ensure that there is no electrical short between the adjacent bonding wires 230, even if the first metal wire 231 and the second metal wire 232 contact to the adjacent bonding wires 230.

As shown in FIG. 5, the encapsulant 240 at least encapsulates the bonding wire 230. In one of the specific embodiment, the encapsulant 240 can be formed inside the central slot 214 of the substrate 210 and extends to cover part of the bottom surface 213 near the central slot 214 on which the bonding finger 211 are disposed so that the bonding wire 230 is completely encapsulated. The encapsulant 240 can be further formed on the top surface 212 of the substrate 210 to encapsulate the chip 220 and the die-attaching layer 260 to provide better protection for the chip 220 and the bonding wire 230.

In the present invention, through the specific combination including the bonding wire 230 consisting of the first metal wire 231, the second metal wire 232, and the insulating body 233 to electrically connect the substrate 210 and the chip 220 as a technical mean, the insulating body 233 encapsulates the first metal wire 231 and the second metal wire 232 and provides the constant gap S between two metal wires 231 and 232 to make both metal wires 231 and 232 parallel to each other without any physical contacts. Therefore, the inductance and resistance between the chip 220 and the substrate 210 can greatly be reduced to enhance the electrical performance of the package. Furthermore, the bonding wire 230 electrically connects the substrate 210 with the chip 220 since the first metal wire 231 and the second metal wire 232 of the bonding wire 230 can be bonded to the same electrical connection on the substrate 210 as well as on the chip 220 in one single wire-bonding process. Therefore, the processing steps as well as the processing time of wire bonding can greatly be reduced with the same productivity as the electrical connections using single bonding wire.

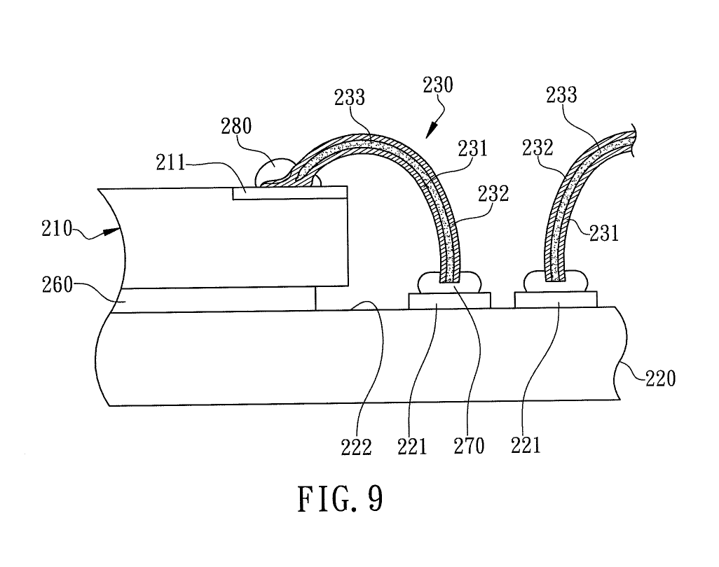

As shown in FIG. 8, the semiconductor package 200 further comprises a first conductive bump 270 disposed on top of the bonding pads 221 to join to one end of the bonding wire 230. In a preferred embodiment, the first conductive bump 270 can be pre-disposed on the bonding pad 221 of the chip 220 to enhance wire bonding of the bonding wire 230. Furthermore, a second conductive bump 280 is further disposed on the bonding fingers 211 of the substrate 210 to join to the other end of the bonding wire 230 to enhance the electrical connections between the substrate 210 and the chip 220 by the bonding wire 230 where the material of the first conductive bump 270 and the second conductive bump 280 can be chosen to enhance bonding of bonding wires such as gold bumps, solder bumps, lead-free bumps, or bumps with other materials. In a preferred embodiment, the second conductive bump 280 can be pre-disposed on the bonding finger 211 of the substrate 210. During wire-bonding processes, one end of the bonding wire 230 is bonded to the first conductive bump 270 disposed on the bonding pad 221 of the chip 220 to make the first conductive bump 270 as the ball bond for the bonding wire 230. Then the other end of the bonding wire 230 is bonded to the second conductive bump 280 disposed on the bonding finger 211 of the substrate 210. In a variation of the embodiment, as shown in FIG. 9, it is not necessary to bond the second conductive bump 280 on the bonding finger of the substrate 210. After one end of the bonding wire 230 is bonded to the first conductive bump 270, the other end of the bonding wire 230 is directly bonded on the bonding finger 211 of the substrate 210 where one end of the second metal wire 232 is pressed and joined to the corresponding end of the first metal wire 231 to form the wedge bond of the bonding wire 230. Preferably, the second conductive bump 280 is further post-bonded on the bonding finger 211 to cover the pressed and joined portions of the second metal wire 232 and the first metal wire 231. Therefore, the wedge bond of the bonding wire 230 can perfectly be connected between the second conductive bump 280 and the bonding finger 211 to become steadier and enhance the bonding strength between the bonding wire 230 and the bonding finger 211 to avoid peeling of the bonding wire 230 from the bonding finger 211 due to the impact of external forces.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A semiconductor package comprising:
a substrate having at least a bonding finger;
a chip disposed on the substrate and having at least a bonding pad;
at least a bonding wire consisting of an insulating body, a first metal wire, and a second metal wire, wherein the first metal wire and the second metal wire electrically connect the bonding pad to the bonding finger, the insulating body encapsulates the first metal wire and the second metal wire in a manner to make the both metal wires extending in parallel and to provide a constant gap between both metal wires so that the extending sections of the both metal wires do not contact to each other leading to electrical short; and
an encapsulant encapsulating the bonding wire and the chip.

2. The semiconductor package as claimed in claim 1, wherein the length of the gap is equal to the diameter of the insulating body subtracting the diameter of the first metal wire and the diameter of the second metal wire so that the first metal wire and the second metal wire are dispersedly adjacent to a wire surface of the insulating body.

3. The semiconductor package as claimed in claim 2, wherein the first metal wire and the second metal wire are partially exposed from the wire surface of the insulating body.

4. The semiconductor package as claimed in claim 3, wherein the exposed portions of the first metal wire and the second metal wire do not face to another adjacent bonding wire.

5. The semiconductor package as claimed in claim 1, wherein the substrate further has a top surface, a bottom surface, and a central slot, wherein an active surface of the chip is attached to the top surface of the substrate with the bonding pad aligned in the central slot, wherein the bonding wire passes through the central slot.

6. The semiconductor package as claimed in claim 5, wherein the substrate further has a plurality of external connecting pads, wherein the bonding finger and the external connecting pads are disposed on the bottom surface of the substrate.

7. The semiconductor package as claimed in claim 6, further comprising a plurality of external terminals disposed on the external connecting pads.

8. The semiconductor package as claimed in claim 5, further comprising a die-attaching layer adhering the active surface of the chip to the top surface of the substrate.

9. The semiconductor package as claimed in claim 1, further comprising a first conductive bump disposed on the bonding pad, wherein one end of the bonding wire is bonded on the first conductive bump.

10. The semiconductor package as claimed in claim 9, further comprising a second conductive bump pre-disposed on the bonding finger, wherein the other end of the bonding wire is bonded on the second conductive bump.

11. The semiconductor package as claimed in claim 9, further comprising a second conductive bump post-bonded on the bonding finger to cover the pressed and joined portions of the second metal wire and the first metal wire on the bonding finger.

12. The semiconductor package as claimed in claim 1, further comprising a conductive bump post-bonded on the bonding finger to cover the pressed and joined portions of the second metal wire and the first metal wire on the bonding finger.
